(19) United States
(12) Patent Application Publication
(10) Pub. No.: US 2009/0135348 A1
(43) Pub. Date: May 28, 2009

(54) METHODS AND APPARATUS FOR FORMING COLOR FILTER ON ARRAY FLAT PANEL DISPLAYS

(75) Inventor: John M. White, Hayward, CA (US)

Correspondence Address: DUGAN & DUGAN, PC, 245 Saw Mill River Road, Suite 309, Hawthorne, NY, 10532, US

(73) Assignee: APPLIED MATERIALS, INC., Santa Clara, CA (US)

(21) Appl. No.: 12/257,383

(22) Filed: Oct. 23, 2008

Related U.S. Application Data
(60) Provisional application No. 60/983,139, filed on Oct. 26, 2007.

(51) Int. Cl. G02F 1/1335; H01L 21/77

(52) U.S. Cl. 349/106; 438/29; 257/E21.535

(57) ABSTRACT

The present invention provides a self-aligned color filter on array substrate made with a minimum number of masks. The invention includes forming opaque features on a substrate wherein the opaque features include circuit features, applying a pixel matrix material to the substrate, and applying an activation energy to portions of the pixel matrix material through the substrate using the opaque features as a mask. Numerous other aspects are provided.

The present application claims priority to U.S. Provisional Patent Application No. 60/983,139 filed Oct. 26, 2007, and entitled “METHODS AND APPARATUS FOR FORMING COLOR FILTER ON ARRAY FLAT PANEL DISPLAYS” (Attorney Docket No. 12052/L) which is hereby incorporated herein by reference in its entirety for all purposes.

### CROSS-REFERENCE TO RELATED APPLICATIONS

The present application is related to the following commonly-assigned, co-pending U.S. patent applications, each of which is hereby incorporated herein by reference in its entirety for all purposes:

U.S. patent application Ser. No. 11/733,665, Attorney Docket No. 11292 filed on Apr. 10, 2007 entitled “Black Matrix Compositions and Methods of Forming the Same”;

U.S. patent application Ser. No. 11/536,540, Attorney Docket No. 10448 filed on Sep. 28, 2006 entitled “Methods and Apparatus for Adjusting Pixel Fill Profiles”;

U.S. patent application Ser. No. 11/521,577, Attorney Docket No. 10502, filed on Sep. 13, 2006, entitled “Method and Apparatus For Manufacturing a Pixel Matrix of a Color Filter for a Flat Panel Display”;

U.S. Patent Application Ser. No. 60/983,137, Attorney Docket No. 12006/L, filed on even date herewith and entitled “Methods And Apparatus For Curing Pixel Matrix Filter Materials”; and

U.S. patent application Ser. No. 11/737,141 Attorney Docket No. 11548 filed on Apr. 19, 2007 entitled “Methods and Apparatus for Inkjetting Spacers in a Flat Panel Display.”

### FIELD OF THE INVENTION

The present invention relates to manufacturing flat panel displays, and more particularly to methods of integrating a color filter on the thin film transistor array substrate.

### BACKGROUND OF THE INVENTION

Many liquid crystal displays (LCD) include two panels, the thin film transistor (TFT) array panel and the color filter panel. The panels sandwich the liquid crystals. The TFT substrate may include the thin film transistors, storage capacitors, pixel electrodes, pixel electrode window, and interconnect wiring such as the data and gate lines. The second substrate, the color-filter substrate, may contain the pixel matrix material and the color material. The pixel matrix material may be formed into pixel wells by an appropriate means, typically lithography. The color material usually includes three primary colors (for example red, green and blue). The color material may be applied into the pixel wells.

A typical LCD manufacturing sequence is to process the thin film transistor (TFT) array glass substrate and the color filter glass substrates separately. The two panels are then joined in an assembly process in which the liquid crystals are added to form the LCD module. The two panels are joined such that the pixel electrode windows of the TFT array and the pixel wells of the color filter substrate are aligned. Alignment of the two panels is difficult, therefore, alternative approaches are desirable. Thus, what is needed are methods and apparatus for manufacturing flat panel displays that do not require alignment of a color filter to a TFT array panel.

### SUMMARY OF THE INVENTION

In some aspects, the present invention provides a method that includes forming opaque features on a substrate wherein the opaque features include circuit features; applying a pixel matrix material to the substrate; and applying an activation energy to portions of the pixel matrix material through the substrate using the opaque features as a mask.

In other aspects, the present invention provides an apparatus that includes a substrate including a color filter and a thin film transistor array. The substrate is formed by forming opaque features on a substrate wherein the opaque features include circuit features; applying a pixel matrix material to the substrate; and applying an activation energy to portions of the pixel matrix material through the substrate using the opaque features as a mask.

In yet other aspects, the present invention provides an apparatus that includes a substrate including a color filter and a thin film transistor array, wherein the substrate is formed by: forming opaque features on the substrate wherein the opaque features include data lines and gate lines; applying a positive photosensitive pixel matrix material to the substrate; and lithographically exposing portions of the positive photosensitive pixel matrix material through the substrate using the opaque features as a mask.

In still yet other aspects, the present invention provides a system that includes a first substrate with a transistor array and color filter wherein the first substrate is made by: forming opaque features on a substrate wherein the opaque features include circuit features; applying a pixel matrix material to the substrate; and applying activation energy to portions of the pixel matrix material through the substrate using the opaque features as a mask. The system further includes a second substrate having a counter electrode; a sealant for assembling the first substrate and the second substrate; a spacer separating the first substrate and the second substrate; a liquid crystal material between the first substrate and the second substrate; and a polarizer associated with each of the first substrate and the second substrate.

Other features and aspects of the present invention will become more fully apparent from the following detailed description, the appended claims and the accompanying drawings.

### BRIEF DESCRIPTION OF THE DRAWINGS

FIG. 1 is a flow chart depicting an example method according to some aspects of the present invention.

FIGS. 2a-2d are magnified, cross-sectional schematic views of a portion of an example substrate having a color filter on array configuration according to some aspects of the present invention.

FIG. 3 is a magnified, cross-sectional schematic view of a portion of an example TFT-LCD color panel according to some aspects of the present invention.

FIG. 4 is a flowchart that depicts an example method embodiment according to some aspects of the present invention.

### DETAILED DESCRIPTION

An alternative to manufacturing processes that require alignment of a color filter to a TFT array panel is to form the color filter directly on the TFT array substrate. This approach is called color on array (COA).

COA implementation may involve forming, e.g., red, green and blue color materials on the pixel electrode windows of the TFT array substrate. Forming the color materials on the TFT array using conventional semiconductor processing techniques is an expensive process as explained below.

Starting with the TFT array already in place on the substrate, typical semiconductor processing techniques may include applying one of the colors of the color material, red for example, to the TFT array. Then the red color material is lithographically exposed using a mask, developed and etched. The same process steps (with different masks, of course) are repeated for the green and blue color material. Additionally, a black matrix material may also need to be patterned. Therefore, at least three, and perhaps four, lithography steps and their associated masks are needed to form the color material on the TFT array. Masks are expensive. In addition, the lithographic equipment used to expose the masks is extremely costly. Therefore, it is advantageous to reduce the number lithography steps and the number masks needed to make a given product. At the same time, proper alignment of the color material and pixel electrode window must be achieved.

In some embodiments, the current invention includes forming the color material on the TFT array without the use of masks. Starting with the TFT array already in place on the substrate, a pixel matrix material is applied to the substrate. By then applying an activation energy through the substrate (rather than directly to the matrix material or a photoresist as is conventional), the circuitry of the TFT array may be effectively used as a mask. In this way, the activated pixel matrix material may form pixel wells and the unexposed material remains as a pixel matrix. The pixel wells may then be filled (or partially filled) with the appropriate color material using an inkjet printing process that does not require masks.

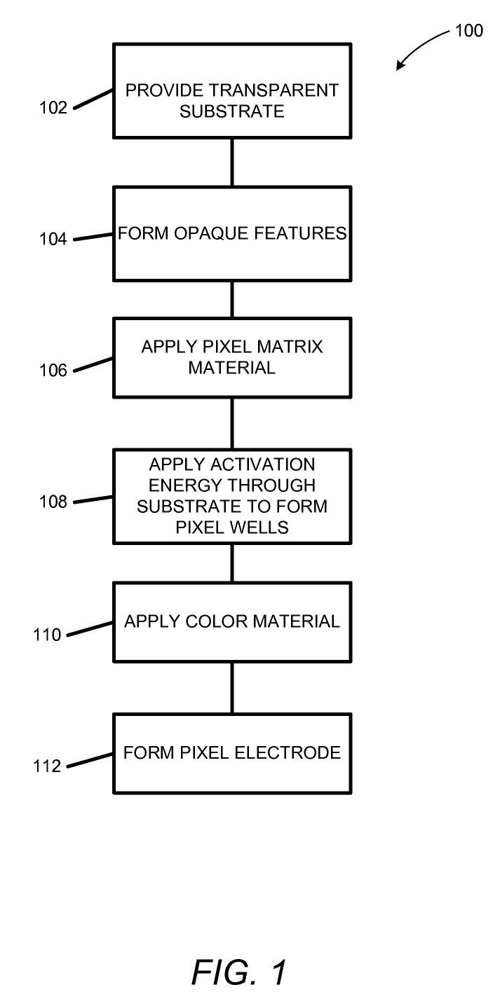

Referring to FIG. 1, embodiments of the present invention is described in more detail. The process 100 begins with a transparent substrate in step 102. The substrate may include, for example, glass, triacetylcellulose (TAC), polycarbonate (PC), polyethersulfone (PES), polyethylenetherephtalate (PET), polyethylenenaphthalate (PEN), polyvinylalcohol (PVC), polymethylmethacrylate (PMMA), cyclo-olefin polymer (COP) and/or another suitable material. For the purposes of the present invention, glass and any other materials that are transparent to activation energy which will be applied in step 108 are acceptable.

In step 104, the opaque features are formed on the substrate. These features may include the circuitry which may be found on the TFT array substrate. The circuitry may include transistors, storage capacitors, data (also called signal) lines to the source or drain, gate lines and other interconnect wiring or circuit features. Generally speaking, a gate line may be formed first by depositing a metal (Cr, Ta, Al, MoTa for example) on the substrate. Typically, the metal gate may be deposited using physical vapor deposition (PVD) and may be patterned using conventional lithographic techniques and a wet etch. While the gate metal is being deposited and patterned, concurrently a first electrode of the storage capacitor may be formed. Another opaque circuit feature includes the semiconductor material used in the transistor. Typically the semiconductor material is silicon ((either amorphous (α-Si), or polycrystalline)). The semiconductor material may include a doped silicon (n or p) layer(s) in addition to an undoped silicon. The silicon is typically deposited using a chemical vapor deposition (CVD) technique and patterned using conventional lithographic techniques and a dry etch. Yet another opaque feature on the substrate is the source and drain data lines. The lines are typically metal (including Ti and Al) deposited by PVD. Likewise the features are typically patterned using conventional lithographic techniques and a dry etching. While the source and drain features are being deposited and patterned, concurrently a second electrode of the storage capacitor may be formed. Although the above described methods may be used, many other alternative methods may be employed to form the opaque features of the display.

As the term ‘transparent’ is used herein with respect to the substrate to mean transparent to activation energy to be applied in step 108, the term ‘opaque’ is used herein with respect to the features to mean opaque to the activation energy applied in step 108. Stated in another way, the opaque features substantially block the passage of the activation energy. Therefore, the opaque features serve at least two functions. The first function is their normal circuit or electronic function. The second function is as a built-in mask as will be further explained in step 108.

Referring to step 106 of the process 100, a blanket of pixel matrix material, also called “black matrix” material, is formed on the substrate. Potentially, the pixel matrix material may be located on either side of the substrate. However, it is difficult to handle, transport, and process two-sided substrates. Therefore, for at least that reason, it may be more desirable to form the blanket of pixel matrix material on the substrate surface having the opaque features. However, in some embodiments, this may not be the case. The blanket of pixel matrix material may be formed on the substrate using an immersing method, a spraying method, a rotating and spin-coating method or any another suitable method to form a coating.

The pixel matrix material will eventually be used to define the pixel wells in which the color material will be deposited. In use, one function of the pixel matrix may be to prevent lateral light leakage. Therefore, the pixel matrix material may include a wide variety or materials including opaque metals, sometimes in combination with their oxides. In addition, the pixel matrix may be made from polymeric resins such as photoresists. Often the photoresists are diffused with carbon and titanium to further reduce reflectivity. The pixel matrix material composition may include a pigment dispersion additive, an initiator, a polymerizable monomer or oligomer or combination thereof (e.g., a photo-polymerizable monomer, thermal-polymerizable monomer, etc.), a binder resin, an epoxy-based monomer, a solvent and a wetting additive. Additional details regarding possible pixel matrix materials and methods of applying the material are given in patent application Ser. No. 11/733,665, Attorney Docket No. 11292, filed on Apr. 10, 2007 entitled “Black Matrix Compositions and Methods of Forming the Same” incorporated herein by reference in it's entirety and for all purposes.

Depending upon the embodiment of the invention, as will be discussed in step 108, the pixel matrix material may or may not be photosensitive.

Referring to step 108, an activation energy is applied to the pixel matrix material through the substrate using the opaque features as a mask. Therefore, if the blanket of pixel matrix material is on the same substrate surface as the opaque features (e.g., the “top surface”) then the activation energy is applied to the bottom surface of the substrate. The energy passes through the substrate and encounters one of two things. The energy may encounter the opaque features or the pixel matrix material. If the opaque features are encountered, the energy is substantially blocked and has little to no impact on the pixel matrix material shielded by the opaque features. Hence, the opaque features mask the pixel matrix material from the effects of the activation energy. If the activation energy encounters the pixel matrix material, the material is altered by the energy. The matrix material is altered in such a way that the pixel matrix material is removed or may later be removed by subsequent process steps. The removal of the pixel material creates pixel wells that are self-aligned with the opaque features. The self-alignment of the pixel wells means that the subsequently applied color material will be self-aligned with pixel electrode windows. This alignment is advantageously achieved without the use of an external mask. Moreover, no special on substrate mask features were needed beyond those already supplied for the electronic function of the panel.

The type of alteration that occurs to the pixel material depends upon the pixel well material and the type of activation energy. The activation energy can be applied in a number of ways including, but not limited to, heat, ultraviolet (UV) radiation, electron beam (e-beam), x-ray or laser light radiation. If an energy source such as ultraviolet radiation is used, then the pixel matrix material should be photosensitive. When the UV light hits a positive tone photosensitive pixel matrix material, the portion of the photoresist that is exposed to light becomes soluble to the photoresist developer and the portion of the photoresist that is unexposed remains insoluble to the photoresist developer.

In that way, the pixel matrix material not protected from exposure by the opaque features is removed forming pixel wells. However, the shielded portions of pixel matrix material remain to form the self-aligned pixel matrix.

If an activation energy is applied by laser ablation, the pixel matrix material does not need to be photosensitive. In laser ablation, the pixel matrix material is removed by irradiation with a laser beam. The material is heated by the absorbed laser energy and evaporates or sublimes. Consequently, a laser wavelength is chosen at which the pixel material sublimes and the opaque materials are effectively unharmed. The end result is similar to the UV example in that the pixel matrix material not shielded by the opaque features is removed to form pixel wells. Whereas the shielded portions of the material remain to form the self-aligned pixel matrix.

In some embodiments, pixel matrix material may be selected such that laser irradiation has a desirable effect on the “philicity” or “phobicity” of the pixel matrix material with respect to the color material. It is desirable to have the sidewalls of a pixel well be “color material-philic” and the top surface of the pixel well be “color material-phobic.” By exposing the sidewalls of an otherwise color material-phobic material to laser ablation, the sidewalls become color material-philic. The resulting pixel matrix structure including a color material-phobic top surface and color material-philic sidewalls is desirable for improved inkjetting of color material. Further details may be found in U.S. patent application Ser. No. 11/521,577, Attorney Docket No. 10502, filed on Sep. 13, 2006, entitled “Method and Apparatus For Manufacturing a Pixel Matrix of a Color Filter for a Flat Panel Display” and incorporated herein by reference in its entirety for all purposes.

In step 110 the color material is applied to the self-aligned pixel wells. In some embodiments, the pixel material of the pixel wells may be cured prior to the application of the color material or concurrently with the color material application as described in U.S. Patent Application Ser. No. 60/983,137, Attorney Docket No. 12006/L, filed on even date herewith and entitled “Methods And Apparatus For Curing Pixel Matrix Filter Materials” and incorporated herein by reference in its entirety for all purposes. The color material may include inks, dyes, pigments or similar materials and are applied to the substrate by either dyeing, diffusing, electro-depositing or printing (including inkjet printing).

A preferred color material and method of deposition is ink (e.g., pigments dissolved in solvent) dispensed by inkjet printing.

Depending upon the surface energy differences between the color material and the side wall surface of the pixel matrix material, the top surface of the color material may be either flat, concave or convex as explained in previously incorporated U.S. patent application Ser. No. 11/733,665, Attorney Docket No. 11292 filed on Apr. 10, 2007 entitled “Black Matrix Compositions and Methods of Forming the Same”. In order to compensate for the differences in surface energies of the color material and the pixel matrix material, a modified inkjetting process is disclosed in U.S. patent application Ser. No. 11/536,540, Attorney Docket No. 10448 filed on Sep. 28, 2006 entitled “Methods and Apparatus for Adjusting Pixel Fill Profiles” which is incorporated herein by reference in its entirety for all purposes.

To finish making the COA panel, a pixel electrode and contact to the transistor is made. The contact may be made via a mask and conventional lithography means through the pixel matrix material. The pixel electrode material is typically a transparent conducting oxide (TCO). As the name suggests, many TCOs are metal oxides. A common TCO is indium tin oxide (ITO). Other TCOs include aluminum doped zinc oxide, antimony tin oxide (ATO), Poly(3,4-ethylenedioxythiophene) or PEDOT (or sometimes PEDT), and Poly(3,4-ethylenedioxythiophene) poly(styrenesulfonate) or PEDOT:PSS. ITO is usually sputtered (PVD) deposited. However, the metal oxide TCOs, in particular ATO, may be directly printed or jetted in place.

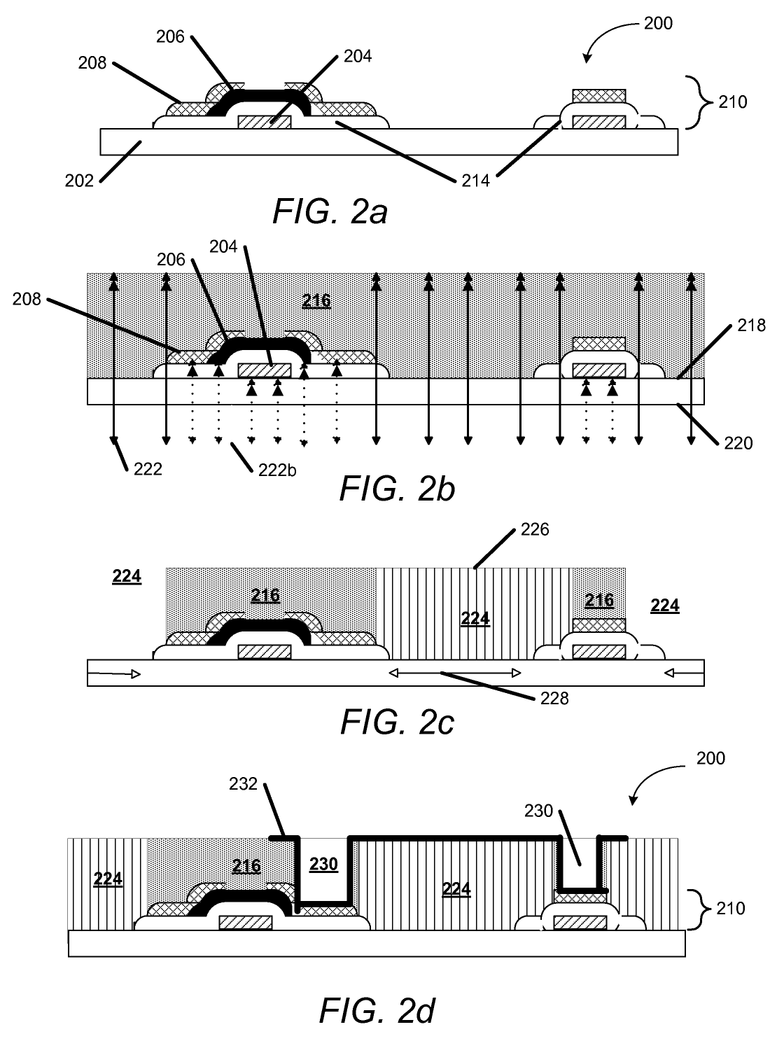

FIGS. 2a through 2d illustrate a color filter on array (COA) panel 200 made by the methods 100 depicted in FIG. 1. Referring to FIG. 2a, the substrate 202 is shown with opaque features including gate line 204, semiconductor layers 206 (both doped and undoped), source and drain lines 208 and capacitor 210. The transistor 212 includes the source, drain, semiconductor layers and the gate. In addition to the opaque features, there are also some typically non-opaque layers 214 which include insulating layers of the transistor 212 and capacitor 210.

In FIG. 2b, the blanket of pixel matrix material 216 is applied to the surface of the substrate having the opaque features (e.g., the “top surface” 218). As stated earlier, it would also be possible to practice the invention with the blanket pixel matrix material applied to the substrate surface not having the opaque features (e.g., the “bottom surface” 220) in which case, the activation energy of step 108 would be applied to the top surface 218.

In FIG. 2b, the activation energy 222 is shown being applied to the pixel matrix material 216 through the substrate 202 from the bottom surface 220 of the substrate. Blocked activation energy 222b is indicated by the shorter dotted arrows. The blocked activation energy 222b is substantially blocked by the opaque features (204, 206, 208, and 210). As indicated above, if the invention were practiced with the pixel matrix material 216 applied to the bottom surface 220 of the substrate, then the activation energy would be applied to the pixel matrix material 216 through the substrate from the top surface 218 of the substrate. In this ‘inverse’ configuration, a portion of the activation energy would still be blocked by the opaque features (204, 206, 208, and 210).

FIG. 2c illustrates the pixel matrix material 216 with the portion exposed to the activation energy removed. The remaining pixel material 216 and substrate 202 form pixel wells 224. FIG. 2c also illustrates one pixel well 224 filled with a color material 226. The color material is substantially aligned with the pixel electrode window 228. Subsequently, color material 226 is added to the remaining unfilled pixel wells 224 to complete the color filter. The color filter (pixel wells filled with color material) is thus created without the use of a mask. In contrast, conventional processes for creating a COA may use at least three masks.

FIG. 2d illustrates the COA 200 with all of the pixel wells 224 filled with color material 226. Additionally, contact holes 230 to the source/drain line 208 and capacitor 210 have been made and the TCO layer 232 has been deposited and patterned.

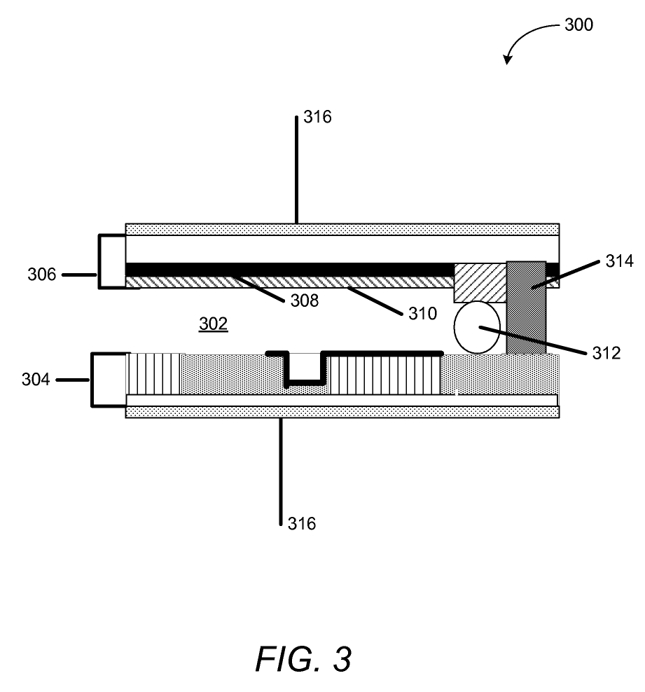

FIG. 3 illustrates the color filter on array described in FIG. 2 made by the methods of FIG. 1 in a flat panel display system 300. Referring to FIG. 3, thin film transistor liquid crystal displays (TFT-LCDs) 300 are composed, primarily by two glass substrates which sandwich the liquid crystals 302. One glass substrate, referred to as the color filter on array (COA) substrate 304 includes the thin film transistors, storage capacitors, interconnect wiring, color filter, and pixel electrodes (TCO). The second substrate referred to as the counter electrode substrate 306 includes the counter electrode 308 and may optionally include an alignment layer 310 or other features not shown. The flat panel display system 300 further includes a spacer 312 to separate the COA substrate 304 and the counter electrode substrate 306; a sealant 314 to assemble the two substrates; and liquid crystals 302 in the cavity between the substrates. Polarizing 316 films are shown on the substrates' outer surfaces but they may also be located on the inner surfaces. For example, starting from the outer surface of the counter electrode substrate 306 and moving toward the liquid crystals 302, the layers in order may be, counter electrode substrate 306, common electrode 308, polarizer 316 and alignment layer 310 (optional). Similarly, starting from the outer surface of the COA substrate 304 and moving toward the liquid crystals 302, the layers in order could be COA substrate 304, polarizer 316 and alignment layer 310 (optional). More details on display systems and methods of making such systems are given in U.S. patent application Ser. No. 11/737,141 Attorney Docket No. 11548/Display/inkjet/RKK filed on Apr. 19, 2007, entitled “Methods and Apparatus for Inkjetting Spacers in a Flat Panel Display,” which is incorporated herein by reference in its entirety for all purposes.

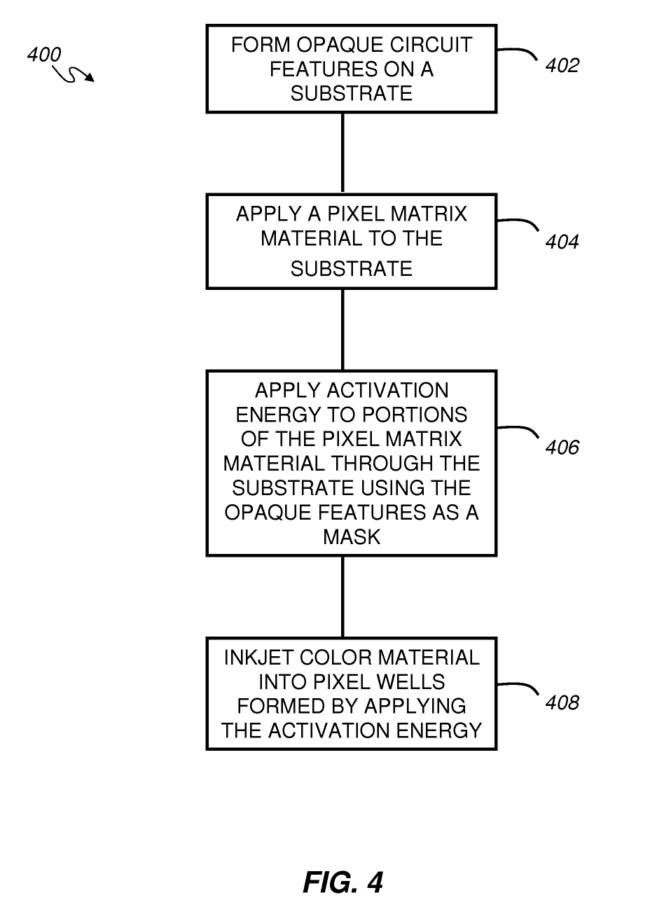

Turning to FIG. 4, a second example method 400 according to embodiments of the present invention is depicted as a flowchart. In step 402, opaque circuit features are formed on a substrate. The circuit features may include electrical components and/or structures (e.g., data lines and gate lines, TFT circuit features, etc.) adapted to drive the display.

In step 404, a pixel matrix material is applied to the substrate (e.g., on the same side of the substrate as the opaque circuit features and/or on the opposite side (e.g., major surface) of the substrate). In some embodiments, the material as applied may be disposed or patterned into a pixel matrix suitable for forming a display.

In step 406, an activation energy may be selectively applied to portions of the pixel matrix material through the substrate using the opaque circuit features as a mask. The activation energy (e.g., ultraviolet radiation; laser ablation energy, etc.) may be applied to either side of the substrate depending on which side the pixel matrix material is on relative to the opaque circuit features being used as a mask. In other words, the opaque circuit features are preferably disposed between the source of the activation energy and the pixel matrix material so that the opaque circuit features can be used as a mask. In some embodiments, the application of the activation energy may selectively cure the pixel matrix material and in others, the application of the activation energy may selectively ablate the pixel matrix material to form pixel wells. In some embodiments, the pixel matrix material includes black matrix material that is phobic to color material to be subsequently deposited. In some embodiments, applying the activation energy includes laser ablation of the black matrix material not shielded by the opaque features.

In step 408, color ink or other material (e.g., OLED materials) may be jetted (e.g., via an inkjet printer) onto the substrate and/or into pixel wells defined by the pixel matrix material (e.g., black matrix material).

While the present invention has been described primarily with reference to manufacturing color filters for flat panel TFT displays, it will be understood that the present invention may also be applied to the manufacture of OLED displays as well as other display types. Further, the present invention may also be applied to spacer formation, polarizing coatings, and nanoparticle circuit forming.

Accordingly, while the present invention has been disclosed in connection with exemplary embodiments thereof, it should be understood that other embodiments may fall within the spirit and scope of the invention, as defined by the following claims.

The invention claimed is:

1. A method comprising:
forming opaque features on a substrate wherein the opaque features include circuit features;
applying a pixel matrix material to the substrate; and
applying an activation energy to portions of the pixel matrix material through the substrate using the opaque features as a mask.

2. The method of claim 1 further comprising inkjet printing color material into pixel wells formed by applying the activation energy.

3. The method of claim 1 wherein the opaque features include data lines and gate lines.

4. The method of claim 1 wherein forming opaque features includes forming TFT circuit features.

5. The method of claim 1 wherein applying a pixel matrix material includes applying the pixel matrix material on the opaque features.

6. The method of claim 1 wherein applying a pixel matrix material includes applying the pixel matrix material on a side of the substrate opposite the opaque features.

7. The method of claim 6 wherein applying an activation energy includes applying the activation energy on a side of the substrate upon which the opaque features are formed.

8. The method of claim 1 wherein applying an activation energy includes applying the activation energy on a side of the substrate opposite the opaque features.

9. The method of claim 1 wherein applying an activation energy forms pixel wells in the pixel matrix material.

10. The method of claim 1 wherein applying the activation energy includes laser ablation of the pixel matrix material not shielded by the opaque features.

11. The method of claim 1 wherein applying the activation energy includes applying ultraviolet radiation.

12. The method of claim 1 wherein the pixel matrix material includes black matrix material.

13. The method of claim 1 wherein the pixel matrix material includes black matrix material that is phobic to color material and applying the activation energy includes laser ablation of the black matrix material not shielded by the opaque features.

14. The method of claim 13 wherein laser ablation of the black matrix material causes the formation of pixel wells with sidewalls that are philic to color material.

15. The method of claim 1 wherein the pixel matrix material is a photosensitive material.

16. The method of claim 15 wherein the photosensitive material is a positive photoresist.

17. An apparatus comprising:
a substrate including a color filter and a thin film transistor array, wherein the substrate is formed by the method of claim 1.

18. The apparatus of claim 17 wherein the color filter includes color material deposited using inkjet printing.

19. An apparatus comprising:
a substrate including a color filter and a thin film transistor array, wherein the substrate is formed by:
forming opaque features on the substrate wherein the opaque features include data lines and gate lines;
applying a positive photosensitive pixel matrix material to the substrate; and
lithographically exposing portions of the positive photosensitive pixel matrix material through the substrate using the opaque features as a mask.

20. A system comprising:
a first substrate with a transistor array and color filter wherein the first substrate is made by:
forming opaque features on a substrate wherein the opaque features include circuit features;
applying a pixel matrix material to the substrate; and
applying activation energy to portions of the pixel matrix material through the substrate using the opaque features as a mask;
a second substrate having a counter electrode;
a sealant for assembling the first substrate and the second substrate;
a spacer separating the first substrate and the second substrate;
a liquid crystal material between the first substrate and the second substrate; and
a polarizer associated with each of the first substrate and the second substrate.
